(19) United States
(12) Patent Application Publication
(10) Pub. No.: US 2020/0006873 A1
(43) Pub. Date: Jan. 2, 2020

(54) CONNECTOR

(71) Applicant: KABUSHIKI KAISHA TOSHIBA, Minato-ku (JP)

(72) Inventor: Shukuyo YAMADA, Yokohama (JP)

(73) Assignee: KABUSHIKI KAISHA TOSHIBA, Minato-ku (JP)

(21) Appl. No.: 16/456,294

(22) Filed: Jun. 28, 2019

(30) Foreign Application Priority Data
Jun. 29, 2018 (JP) 2018-124508

(51) Int. Cl. H01R 12/57; H05K 3/34; H05K 1/18; H01R 12/72; H01R 12/71; H01R 4/02

(52) U.S. Cl. CPC H01R 12/57; H05K 3/34; H05K 1/18; H01R 24/60; H01R 12/716; H01R 4/02; H01R 12/722

(57) ABSTRACT

According to one embodiment, a connector includes a shell including an opening portion into which a plug is removably inserted, and reinforcing terminals which are integrally formed with the shell and are soldered to pads on a wiring substrate. At least the reinforcing terminals adjacent to the opening portion each includes an extending piece which projects from the shell so as to face the wiring substrate, and a leg portion which integrally extends from the extending piece in a direction of opening of the opening portion of the shell and includes a joint piece to be soldered to the pad.

### CROSS-REFERENCE TO RELATED APPLICATIONS

This application is based upon and claims the benefit of priority from Japanese Patent Application No. 2018-124508, filed Jun. 29, 2018, the entire contents of which are incorporated herein by reference.

### FIELD

Embodiments described herein relate generally to a surface mount connector.

### BACKGROUND

A surface mount connector comprises a plurality of reinforcing terminals for securing the strength of mounting on a wiring substrate. The reinforcing terminals are integrally formed with a shell which is formed of sheet metal and constitutes the external form of the connector, and project toward the sides of the shell from the right and left side surfaces of the shell, for example. Each of the reinforcing terminals has a distal end portion bent toward the front surface of the wiring substrate, and the distal end portion is soldered to a pad on the front surface of the wiring substrate.

Furthermore, the shell has an opening portion where a plug of a USB device is inserted or removed, for example. To counter a load applied to the shell when the plug is inserted or removed, the reinforcing terminals of the shell are distributed in the front end portion of the shell which is adjacent to the opening portion and the rear end portion of the shell which is opposite to the opening portion.

When the plug is inserted into or removed from the shell of the connector, for example, if the plug is wrenched in the thickness direction of the wiring substrate, the shell exhibits such a behavior that the shell is forced to rotate in the thickness direction of the wiring substrate with respect to a portion close to the front end portion of the shell having the opening portion, which serves as a fulcrum.

Therefore, the reinforcing terminal located in the rear end portion of the shell which is far from the opening portion receives the behavior of the shell as a tensile or compressive load. On the other hand, the reinforcing terminal located in the front end portion of the shell which is close to the opening portion is more likely to be subjected to not only a mere tensile or compressive load but also a load associated with the rotation (wrench) with respect the front end portion of the shell which serves as a fulcrum.

In the structure of a conventional reinforcing terminal, the load applied to the reinforcing terminal when the shell exhibits the rotating behavior cannot be absorbed, and the resistance to the load of the reinforcing terminal located in the front end portion in particular is reduced.

As a result, an excessive stress is inevitably applied to a solder joint portion between the reinforcing terminal located in the front end portion of the shell and the pad, and the solder joint portion may crack or the reinforcing terminal may be detached from the pad.

### BRIEF DESCRIPTION OF THE DRAWINGS

FIG. 1 is a perspective view showing a state where a micro USB connector according to the first embodiment is mounted on a wiring substrate.

FIG. 2 is an exploded perspective view showing the positional relationship between the micro USB connector according to the first embodiment and a cut portion of the wiring substrate.

FIG. 3 is an enlarged perspective view showing a portion of one second reinforcing terminal.

FIG. 4 is a perspective view showing a state where a plug of a USB device is inserted in the micro USB connector according to the first embodiment.

FIG. 5 is a cross-sectional view showing a state where the plug of the USB device is inserted in the micro USB connector according to the first embodiment.

FIG. 6 is a perspective view showing a state where a plug of a USB device is inserted in a micro USB connector according to the second embodiment.

FIG. 7 is a perspective view of a micro USB connector showing a modification example 1 of the second embodiment.

FIG. 8 is a perspective view of a micro USB connector showing a modification example 2 of the second embodiment.

FIG. 9 is a plan view showing a state where a micro USB connector is mounted on a wiring substrate in the third embodiment.

FIG. 10 is an enlarged perspective view showing a portion of one second reinforcing terminal in the third embodiment.

### DETAILED DESCRIPTION

Embodiments described herein aim to obtain a connector which can increase the resistance to a wrench of a reinforcing terminal and can sufficiently secure the strength of mounting of a shell on a wiring substrate.

In general, according to one embodiment, there is provided a surface mount connector comprising a shell comprising an opening portion into which a plug is removably inserted, and a plurality of reinforcing terminals which are integrally formed with the shell and are soldered to a plurality of pads on a wiring substrate. At least the reinforcing terminals adjacent to the opening portion of the shell each comprises an extending piece which projects from the shell so as to face the wiring substrate, and a leg portion which integrally extends from the extending piece in a direction of opening of the opening portion of the shell and comprises a joint piece to be soldered to the pad.

### First Embodiment

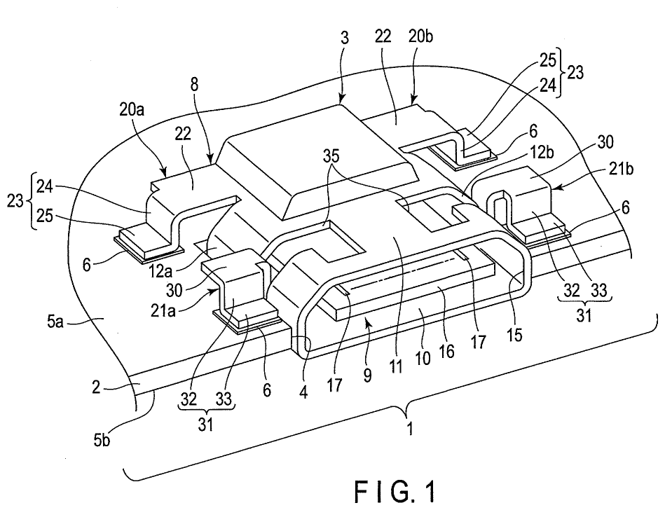

The first embodiment will be described hereinafter with reference to FIGS. 1 to 5.

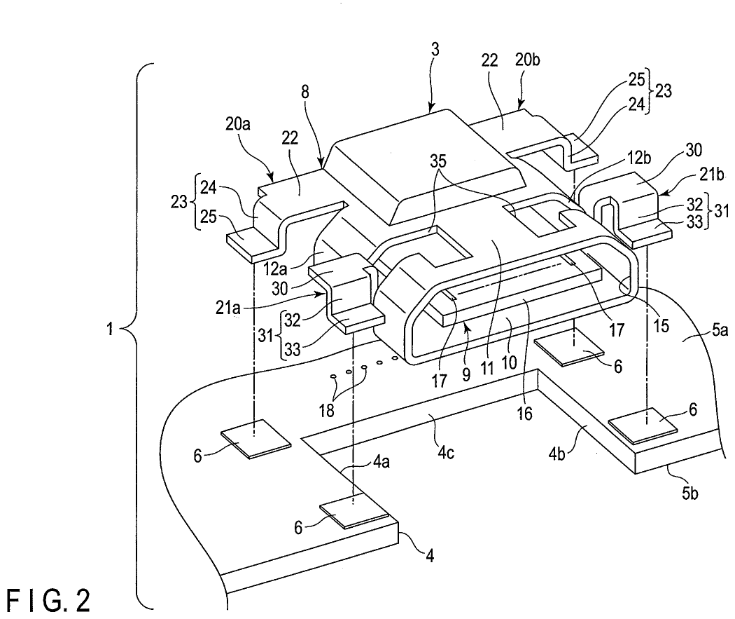

FIG. 1 is a perspective view of a circuit board 1 used in an electronic device such as a mobile phone or a digital camera, and FIG. 2 is an exploded perspective view of the circuit board 1 of FIG. 1. As shown in FIGS. 1 and 2, the circuit board 1 of the present embodiment comprises a wiring substrate 2 and a micro USB connector 3 mounted on the wiring substrate 2, as main elements. The micro USB connector 3 is an example of the surface mount connector.

According to the present embodiment, the wiring substrate 2 comprises a cut portion 4 such as that shown in FIG. 2. The cut portion 4 is cut so as to open in one of the outer edges of the wiring substrate 2. More specifically, the cut portion 4 has first to third edge portions 4a, 4b and 4c. The first edge portion 4a and the second edge portion 4b face each other across a space so as to be continuous with one of the outer edges of the wiring substrate 2. The third edge portion 4c connects one end of the first edge portion 4a and one end of the second edge portion 4b. Therefore, the first to third edge portions 4a, 4b and 4c define a rectangular space where the micro USB connector 3 is set in cooperation with each other.

In addition, the wiring substrate 2 has a front surface 5a and a rear surface 5b which are flat and continuous with the cut portion 4. Four reinforcing pads 6 are provided on the front surface 5a of the wiring substrate 2. The reinforcing pads 6 are arranged on the front surface 5a of the wiring substrate 2 so as to be adjacent to four corner portions of the cut portion 4, respectively.

According to the present embodiment, the micro USB connector 3 is the so-called offset type connector and is mounted on the front surface 5a of the wiring substrate 2 in a state of being dropped in the cut portion 4 of the wiring substrate 2. In the present embodiment, the surface mount connector is not limited to a micro USB connector 3 but may be a microphone jack connector where a microphone plug of an external microphone is inserted or removed or may be a remote control connector where a plug of a remote control cable is inserted or removed, and the type of the connector is not particularly limited.

In addition, the surface mount connector is not limited to an offset type connector which is dropped in the cut portion 4 of the wiring substrate 2, and can be implemented as an on-board type connector which is placed on the front surface or rear surface of the wiring substrate 2.

As shown in FIGS. 1 and 2, the micro USB connector 3 comprises a shell 8 and a terminal block 9, as main elements. The shell 8 is an element constituting the external form of the micro USB connector 3, and is formed in the shape of an oblate and rectangular tube using sheet metal, for example.

More specifically, the shell 8 has a bottom plate portion 10, a top plate portion 11 and right and left side plate portions 12a and 12b. The bottom plate portion 10 and the top plate portion 11 face each other across a space in the thickness direction of the micro USB connector 3. One side plate portion 12a stands so as to connect one side edge of the bottom plate portion 10 and one side edge of the top plate portion 11. The other side plate portion 12b stands so as to connect the other side edge of the bottom plate portion 10 and the other side edge of the top plate portion 11. Therefore, the side plate portions 12a and 12b face each other across a space in the width direction of the micro USB connector 3.

In addition, the front edge of the bottom plate portion 10, the front edge of the top plate portion 11 and the front edges of the right and left side plate portions 12a and 12b define an opening portion 15 in cooperation with each other. The opening portion 15 is an element where, for example, a plug 14 of a USB device is detachably fitted, and has the shape of a long and thin opening in the width direction of the micro USB connector 3.

The terminal block 9 is formed of synthetic resin material having electrically insulating properties and is accommodated in the shell 8. The terminal block 9 has a plate-shaped tongue portion 16. The tongue portion 16 extends toward the opening portion 15 of the shell 8.

A plurality of contact terminals 17 are supported on the terminal block 9. The contact terminals 17 are arranged and spaced apart from each other in the width direction of the micro USB connector 3. One ends of the contact terminals 17 are guided on the upper surface and lower surface of the tongue portion 16 of the terminal block 9.

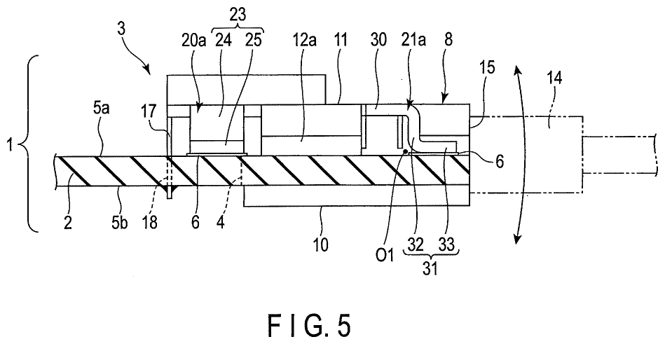

As shown in FIG. 5, the other ends of the contact terminals 17 are located in the rear end portion of the terminal block 9 and are bend downward toward the wiring substrate 2. The lower end portions of the contact terminals 17 are inserted into a plurality of through holes 18 penetrating the wiring substrate 2, and are soldered to the through holes 18. As a result, the contact terminals 17 of the micro USB connector 3 are electrically connected to a conductive layer of the wiring substrate 2.

As shown in FIGS. 1 to 4, a pair of first reinforcing terminals 20a and 20b and a pair of second reinforcing terminals 21a and 21b are integrally formed with the shell 8 of the micro USB connector 3. The first reinforcing terminals 20a and 20b and the second reinforcing terminals 21a and 21b are plate-shaped elements which fix the micro USB connector 3 in the state of being dropped in the cut portion 4 of the wiring substrate 2.

In the present embodiment, the first reinforcing terminals 20a and 20b and the second reinforcing terminals 21a and 21b are provided in the four corners of the shell 8 so as to correspond to the reinforcing pads 6 of the wiring substrate 2, for example. The positions of the first reinforcing terminals 20a and 20b and the second reinforcing terminals 21a and 21b with respect to the shell 8 are not limited to the four corners of the shell 8 but are appropriately set in accordance with the type, size or the like of the connector, for example.

The first reinforcing terminals 20a and 20b are located in the rear end portion of the shell 8 which is far from the opening portion 15 where the plug 14 is inserted or removed. According to the present embodiment, the first reinforcing terminals 20a and 20b are integrally cut and raised from the bottom plate portion 10 and the side plate portions 12a and 12b of the shell 8 in the rear end portion of the shell 8.

More specifically, the first reinforcing terminals 20a and 20b comprise extending pieces 22 which horizontally project from the top plate portion 11 of the shell 8 toward the sides in the width direction of the shell 8, respectively, and leg portions 23 which are continuous with the projecting ends of the extending pieces 22, respectively.

The projecting end portion of the extending piece 22 of one first reinforcing terminal 20a crosses over the first edge portion 4a defining the cut portion 4 of the wiring substrate 2. The projecting end portion of the extending piece 22 of the other first reinforcing terminal 20b crosses over the second edge portion 4b defining the cut portion 4 of the wiring substrate 2. Therefore, the projecting end portions of the extending pieces 22 of the first reinforcing terminals 20a and 20b face the front surface 5a of the wiring substrate 2.

The leg portion 23 has a standing piece 24 which is bent downward from the projecting end of the extending piece 22, and a joint piece 25 which is bent toward the opposite side to the shell 8 from the lower end of the standing piece 24. The standing piece 24 stands so as to connect the extending piece 22 and the joint piece 25, and extends in the direction of insertion or removal of the plug 14 with respect to the shell 8.

The joint piece 25 is soldered to the reinforcing pat 6 of the wiring substrate 2. As a result, a solder joint portion is formed between the joint piece 25 of each of the first reinforcing terminals 20a and 20b and the reinforcing pad 6, and each of the first reinforcing terminals 20a and 20b is fixed to the wiring substrate 20 by the solder joint portion.

The second reinforcing terminals 21a and 21b are located in the front end portion of the shell 8 which is adjacent to the opening portion 15 where the plug 14 is inserted or removed. According to the present embodiment, the second reinforcing terminals 21 and 21b are integrally cut and raised from the side plate portions 12a and 12b and the top plate portion 11 of the shell 8 in the front end portion of the shell 8.

More specifically, the second reinforcing terminals 21a and 21b comprise extending pieces 30 which horizontally project from the upper end portions of the side plate portions 12a and 12b of the shell 8 toward the sides in the width direction of the shell 8, respectively, and leg portions 31 which are continuous with the extending pieces 30, respectively.

The extending piece 30 of one second reinforcing terminal 21a crosses over the first edge portion 4a defining the cut portion 4 of the wiring substrate 2. The extending piece 30 of the other second reinforcing terminal 21b crosses over the second edge portion 4b defining the cut portion 4 of the wiring substrate 2. Therefore, the extending pieces 30 of the second reinforcing terminals 21a and 21b face the front surface 5a of the wiring substrate 2.

The leg portion 31 extends from the extending piece 30 in the direction of opening of the opening portion 15 where the plug 14 is inserted or removed. That is, the leg portion 31 has a standing piece 32 which is bent downward from the end located on the opening portion 15 side of the extending piece 30, and a joint piece 33 which is bent in the direction of opening of the opening portion 15 from the lower end of the standing piece 32. The standing piece 32 stands so as to connect the extending piece 30 and the joint piece 33, and extends in a direction substantially orthogonal to the direction of insertion or removal of the plug 14 with respect to the shell 8.

In addition, the leg portion 31 is formed by bending the bent portion which is cut and raised from the shell 8 twice, and is integrally formed with the extending piece 30.

In a state where the second reinforcing terminals 21a and 21b are cut and raised from the shell 8, as shown in FIG. 3 in which one second reinforcing terminal 21a is shown as a typical example, a cutout hole 35 is formed in the side portion 12a and the top plate portion 11 of the shell 8.

The cutout hole 35 has a first opening area 35a corresponding to the extending piece 30 and a second opening area 35b corresponding to the leg portion 31. The first opening area 35a opens from the side plate portion 12a to the top plate portion 11 of the shell 8. The second opening area 35b opens in the top plate portion 11 of the shell 8 continuously with the first opening area 35a, and is cut from the first opening area 35a toward the opening portion 15 of the shell 8.

The joint piece 33 of each of the second reinforcing terminals 21a and 21b is soldered to the reinforcing pad 6 of the wiring substrate 2. As a result, a solder joint portion is formed between the joint piece 33 of each of the second reinforcing terminals 21a and 21b and the reinforcing pad 6, and each of the second reinforcing terminals 21a and 21b is fixed to the wiring substrate 2 by the solder joint portion.

In a state where the joint piece 33 of each of the second reinforcing terminals 21a and 21b is soldered to the reinforcing pad 6 of the wiring substrate 2, the leg portion 31 is shifted toward the opening portion 15 of the shell 8 at the projecting end of the extending piece 30, and the extending piece 30 drawn from the shell 8 is held almost in a state of being held at one side.

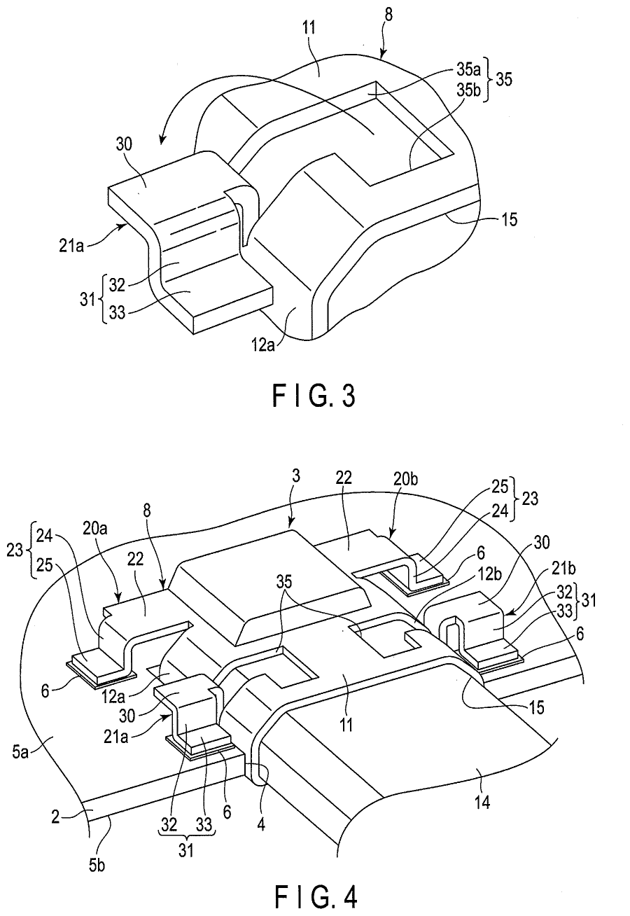

FIGS. 4 and 5 show a state where the plug 14 of the USB device is inserted in the opening portion 15 of the shell 8. When the plug 14 is inserted in the opening portion 15 of the shell 8, the distal end portion of the plug 14 is surrounded by the bottom plate portion 10, the top plate portion 11 and the side plate portions 12a and 12b of the shell 8. In addition, a plurality of conductive terminals (not shown) provided in the plug 14 are in contact with the contact terminals 17 of the micro USB connector 3. As a result, the plug 14 and the micro USB connector 3 are electrically connected to each other.

On the other hand, if the plug 14 is vertically wrenched in the thickness direction of the wiring substrate 2 when being removed from the opening portion 15 of the shell 8, the upper surface or lower surface of the plug 14 may interfere with the shell 8 near the opening portion 15. When the plug 14 interferes with the shell 8, as indicated by an arrow in FIG. 5, a force which forces the shell 8 to vertically rotate is applied to the shell 8.

As a result, the shell 8 exhibits such a behavior that the shell 8 vertically rotates about a virtual fulcrum O1 generated near the opening portion 15 with respect to the wiring substrate 2.

In addition, for example, if the shell 8 is brought into contact with the housing of an electronic device accommodating the wiring substrate 2 near the opening portion 15 in accordance with the interference between the plug 14 and the shell 8, this contact portion will serve as the virtual fulcrum O1. On the other hand, even if the shell 8 is not brought into contact with the housing, the position of the virtual fulcrum O1 is determined depending on the rigidity of the wiring substrate 2 which is determined depending on where the wiring substrate 2 is fixed to the housing, for example. Therefore, the position of the virtual fulcrum O1 is not unconditionally determined but is generally located near the opening portion 15 of the shell 8 in many cases.

As shown in FIG. 5, if the shell 8 exhibits a rotating behavior, the first reinforcing terminals 20a and 20b which are far from the fulcrum O1 serving as the rotation center of the shell 8 receive the behavior of the shell 8 mainly as a tensile or compressive load perpendicular to the front surface 5a of the wiring substrate 2 and is less likely to be subjected to a load associated with the rotation (twist) of the shell 8.

In addition, in each of the first reinforcing terminals 20a and 20b, the standing piece 24 of the leg portion 23 continuous with the extending piece 22 stands in the direction of insertion or removal of the plug 14 with respect to the shell 8, and the joint piece 25 projects from the lower end of the standing piece 24 in the direction of separating from the shell 8 toward the side of the shell 8.

As a result, each of the first reinforcing terminals 20a and 20b can withstand a tensile or compressive load perpendicular to the front surface 5a of the wiring substrate 2 without employing an elastically deformable structure, and the resistance of each of the first reinforcing terminals 20a and 20b with respect to a tension or compressive load will be maintained.

Consequently, a stress applied to the solder joint portion between the joint piece 25 of each of the first reinforcing terminals 20a and 20b and the reinforcing pad 6 of the wiring substrate 2 can be moderated, and the damage to the solder joint portion can be prevented.

The second reinforcing terminals 21a and 21b located in the front end portion of the shell 8 are located near the fulcrum O1 serving as the rotation center of the shell 8. Therefore, if the shell 8 exhibits the rotating behavior, the second reinforcing terminals 21a and 21b receive most of the behavior of the shell 8 not only as a mere tensile or compressive load but also as a load associated with the rotation (twist) about the fulcrum O1.

According to the present embodiment, the leg portion 31 of each of the second reinforcing terminals 21a and 21b integrally extends from the extending piece 30 which projects toward the side of the shell 8 in the direction of opening of the opening portion 15 where the plug 14 is inserted or removed. In other words, the leg portion 31 is shifted toward the opening portion 15 of the shell 8 at the projecting end of the extending piece 30, and the extending piece 30 drawn from the shell 8 is held almost in the state of being held at one side.

Therefore, if the load associated with the rotation (twist) of the shell 8 is applied to each of the second reinforcing terminals 21a and 21b, the extending piece 30 of each of the second reinforcing terminals 21a and 21b elastically deforms and absorbs the load associated with the rotation (twist) of the shell 8. That is, the extending piece 30 of each of the second reinforcing terminals 21a and 21b is implemented as being elastic with respect to the rotating behavior of the shell 8, and the resistance to the load associated with the rotation (twist) of the shell 8 of each of the second reinforcing terminals 21 and 21b increases.

As a result, the stress applied to the solder joint portion between the joint piece 33 of each of the second reinforcing terminals 21a and 21b and the reinforcing pad 6 of the wiring substrate 2 can be moderated, and the damage to the solder joint portion can be prevented.

According to the first embodiment, the resistance of each of the second reinforcing terminals 21a and 21b which are more likely to be subjected to the load associated with the rotation (twist) of the shell 8 can be increased by employing a simple structure, that is, changing the orientation of each of the second reinforcing terminals 21a and 21b with respect to the shell 8. As a result, the reliability of mounting of the micro USB connector 3 on the wiring substrate 2 increases, and the durability of the circuit board 1 improves.

In addition, since the leg portion 31 of each of the second reinforcing terminals 21a and 21b can be formed by further bending the bent portion which is cut and raised from the shell 8, only the bending shape of the conventional second reinforcing terminal needs to be changed. Therefore, new manufacturing equipment will not be required, the number of manufacturing steps will not be significantly increased, and the manufacturing cost of the shell 8 can be reduced.

### Second Embodiment

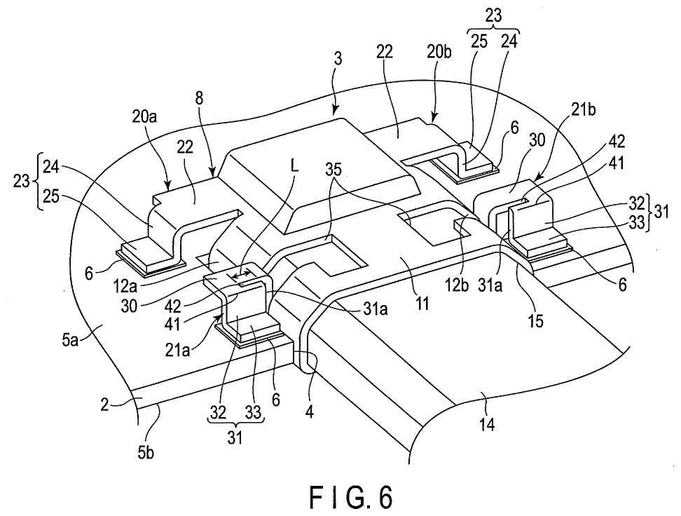

FIG. 6 shows the second embodiment. The second embodiment is different from the first embodiment in a part of the structure of each of the second reinforcing terminals 21a and 21b but is the same as the first embodiment in the other structure of the micro USE connector 3. Therefore, in the second embodiment, the same constituent elements as the first embodiment will be denoted by the same reference numbers and detailed description thereof will be omitted.

According to the first embodiment described above, when a load associated with the rotation (twist) of the shell 8 is applied to each of the second reinforcing terminals 21a and 21b, the extending piece 30 of each of the second reinforcing terminals 21a and 21b elastically deforms and absorbs the load associated with the rotation (twist).

At this time, the load which cannot be absorbed in the extending piece 30 is applied from the extending piece 30 to the solder joint portion between the joint piece 33 and the reinforcing pad 6 of the wiring substrate 2 via the standing piece 32 of the leg portion 31.

The analysis of the inventors of the present application shows that, when a load which cannot be absorbed in the extending piece 30 is applied to the solder joint portion, a stress locally concentrated on a portion close to the boundary between the joint piece 33 and the standing piece 32 of the solder joint portion, in particular, a portion close to the shell 8 at the boundary.

Therefore, in the second embodiment, one slit 42 is formed in a corner portion 41 defined by the extending piece 30 and the extending piece 32 of the leg portion 31 of each of the second reinforcing terminals 21a and 21b as shown in FIG. 6.

The corner portion 41 is located at the boundary between the extending piece 30 and the standing piece 32. The slit 42 is linearly cut from an inner edge 31a side of the leg portion 31 which is adjacent to the shell 8 in the direction of separating from the shell 8. In addition, the slit 42 penetrates the corner portion 41 in the thickness direction.

According to the second embodiment, the extending piece 30 and the standing piece 32 are partially separated from each other by the presence of the slit 42. Therefore, the extending piece 30 elastically deforms more easily, of course, but besides that, the load associated with the rotation (twist) of the shell 8 which cannot be absorbed even with the elasticity of the extending piece 30 is less likely to be transferred from the extending piece 30 to the standing piece 32.

Furthermore, since the slit 42 is cut from the inner edge 31a side of the leg portion 31 which is adjacent to the shell 8, the load which cannot be absorbed in the extending piece 30 can be prevented from being concentrated on a side close to the shell 8 of the standing piece 32.

As a result, the stress which has been concentrated on a specific portion close to the shell 8 of the solder joint portion between the joint piece 33 and the reinforcing pad 6 can be moderated. Therefore, damage to the solder joint portion can be reliably prevented.

Furthermore, as a length L of the slit 42 increases or decreases, the intensity of the load applied from the extending piece 30 to the solder joint portion via the standing piece 32 changes, and the stress moderation effect of the slit 42 changes. Therefore, the length L of the slit 42 can be appropriately set in accordance with, for example, the type of the connector, the usage environment of the connector or the like.

Note that the slit 42 does not necessarily penetrate the corner portion 41 and may be a linear groove having a predetermined depth.

### MODIFICATION EXAMPLE 1 OF SECOND EMBODIMENT

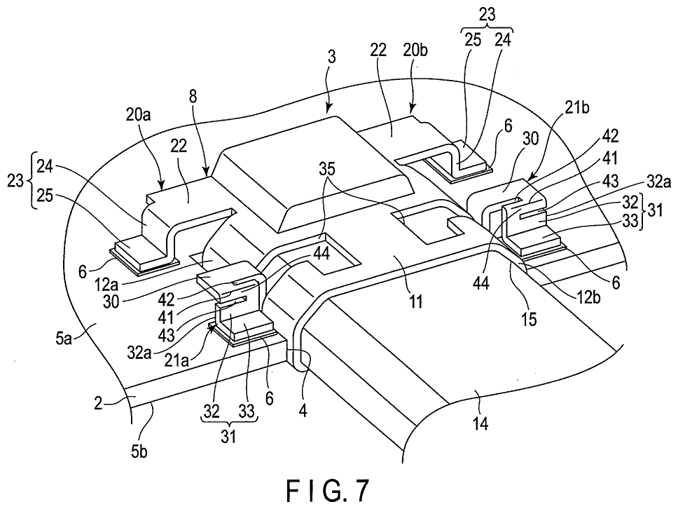

FIG. 7 shows a modification example 1 of the second embodiment. In the modification example 1, another slit 43 is added to the corner portion 41 of the leg portion 31. The other slit 43 extends parallel to the slit 42 at a position shifted from the slit 42 in the direction of the upper end portion of the standing piece 32. In addition, the other slit 43 is cut from an outer edge 32a side of the standing piece 32 which is located on the opposite side to the shell 8 linearly toward the shell 8.

In other words, the other slit 43 is cut in the upper end portion of the standing piece 32 from the opposite side to the slit 42. Accordingly, two slits 42 and 43 define a load transfer portion 44 which is bent in a crank shape in the corner portion 41 of each of the second reinforcing terminals 21a and 21b.

According to the modification example 2, the load associated with the rotation (twist) of the shell 8 which cannot be absorbed even with the elasticity of the extending piece 30 is transferred from the extending piece 30 to the standing piece 32 via the load transfer portion 44 which is bent in a crank shape, and therefore the length of a load transfer path from the extending piece 30 to the standing piece 32 increases. Furthermore, the rigidity of each of the second reinforcing terminals 21a and 21b is reduced by the presence of two slits 42 and 43. As a result, the second reinforcing terminals 21a and 21b sag down more easily.

Therefore, the load associated with the rotation (twist) of the shell 8 is less likely to be transferred from the extending piece 30 to the joint piece 33 via the standing piece 32, and the stress concentrated on a specific portion of the solder joint portion of each of the second reinforcing terminals 21a and 21b can be moderated.

### MODIFICATION EXAMPLE 2 OF SECOND EMBODIMENT

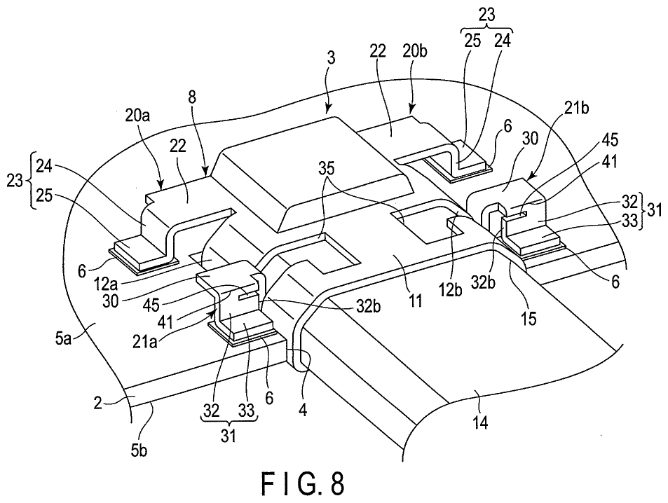

FIG. 8 shows a modification example 2 of the second embodiment. In the modification example 2, one slit 45 is formed in the upper end portion of the standing piece 32 of each of the second reinforcing terminals 21a and 21b. The slit 45 is linearly cut from the inner edge 32b side of the standing piece 32 which is adjacent to the shell 8 in the direction of separating from the shell 8.

In the structure of the modification example 2 also, the extending piece 30 and the standing piece 32 are partially separated from each other by the presence of the slit 45, and the stress concentrated on a specific portion of the solder joint portion of each of the second reinforcing terminals 21a and 21b can be moderated.

### Third Embodiment

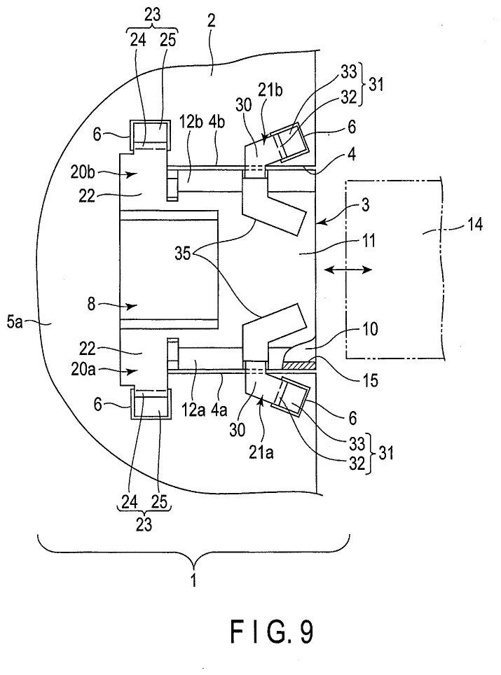

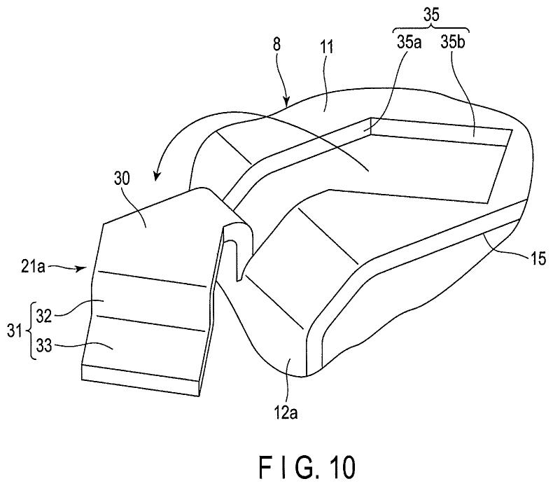

FIGS. 9 and 10 show the third embodiment. The third embodiment is different from the first embodiment in the orientation of each of the second reinforcing terminals 21a and 21b but is the same as the first embodiment in the other structure. Therefore, in the third embodiment, the same constituent elements as the first embodiment are denoted by the same reference numbers, and detailed description thereof will be omitted.

As shown in FIGS. 9 and 10, the extending piece 30 of each of the second reinforcing terminals 21a and 21b projecting toward the side of the shell 8 leans in such a manner that, as the extending piece 30 extends in the direction of the opening portion 15 of the shell 8, the extending piece 30 separates from the shell 8 toward the side of the shell 8. Therefore, regarding the leg portion 31 continuous with the extending piece 30 also, the joint piece 33 leans in the same direction as the extending piece 30 with respect to the shell 8.

That is, as shown in FIG. 9, the pair of second reinforcing terminals 21a and 21b are arranged so as to spread in the directions of separating from each other on both sides of the shell 8. For this reason, the joint piece 33 of each of the second reinforcing terminals 21a and 21b is soldered to the reinforcing pad 6 of the wiring substrate 2 at a position which is farther from the shell 8 toward the side of the shell 8 as compared to the first embodiment.

According to the third embodiment, the second reinforcing terminals 21a and 21b can support the front end portion of the shell 8 over a wider span than those of the first embodiment. Therefore, even when being subjected to the load associated with the rotation (twist) of the shell 8, the second reinforcing terminals 21a and 21b can stand firmly. As a result, it is possible to produce a special effect, that is, to stabilize the position of the micro USB connector 3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, in the case of forming a plurality of slits in the second reinforcing terminal of the connector, at least one slit should preferably be located on the inner edge side of the second reinforcing terminal which is adjacent to the shell.

What is claimed is:

1. A surface mount connector comprising:
a shell comprising an opening portion into which a plug is removably inserted; and
a plurality of reinforcing terminals which are integrally formed with the shell and are connected to a plurality of pads on a wiring substrate, wherein
at least the reinforcing terminals adjacent to the opening portion of the shell each comprises
an extending piece which projects from the shell so as to face the wiring substrate, and
a leg portion which integrally extends from the extending piece in a direction of opening of the opening portion of the shell and comprises a joint piece to be connected to the pad.

2. The connector of claim 1, wherein
the leg portion of the reinforcing terminal comprises a standing piece which bridges the extending piece and the joint piece, and
the standing piece extends in a direction crossing a direction of insertion or removal of the plug with respect to the shell.

3. The connector of claim 2, wherein the reinforcing terminals each have at least one slit in at least one of the extending piece and the standing piece.

4. The connector of claim 1, wherein the extending piece of the reinforcing terminal is elastic with respect to a rotating behavior of the shell in a thickness direction of the wiring substrate.

5. The connector of claim 1, wherein the reinforcing terminals each comprising the extending piece and the leg portion are located near a fulcrum of rotation of the shell when the shell exhibits such a rotating behavior that the shell is forced to rotate in a thickness direction of the wiring substrate.

6. The connector of claim 1, wherein
the shell surrounds the plug continuously with the opening portion, and
the reinforcing terminals are integrally cut and raised from the shell.

7. The connector of claim 1, wherein
the wiring substrate comprises a cut portion which is cut so as to open in an outer edge of the wiring substrate, and
the reinforcing terminals of the shell are connected to the pads of the wiring substrate in a state where the shell is dropped in the cut portion of the wiring substrate.

8. The connector of claim 1, wherein the reinforcing terminals are connected to the pads by means of soldering.

9. The connector of claim 3, wherein
one slit is formed in a corner portion defined by the extending piece and the standing piece of the leg portion in each of the reinforcing terminals adjacent to the opening portion of the shell, and
the one slit is cut from an inner edge side of the leg portion which is adjacent to the shell linearly in a direction of separating from the shell.

10. The connector of claim 9 wherein
another slit is added to the corner portion,
the other slit extends parallel to the one slit at a position shifted from the one slit toward an upper end portion of the standing piece, and
the other slit is cut from an outer edge side of the standing piece which is located on an opposite side to the shell linearly toward the shell.

11. The connector of claim 3, wherein
one slit is formed in an upper end portion of the standing piece in each of the reinforcing terminals adjacent to the opening portion of the shell, and
the one slit is cut from an inner edge side of the standing piece which is adjacent to the shell linearly in a direction of separating from the shell.

12. The connector of claim 1, wherein
the reinforcing terminals include
a pair of first reinforcing terminals which are far from the opening portion of the shell, and
a pair of second reinforcing terminals which are adjacent to the opening portion of the shell,
the first reinforcing terminals and the second reinforcing terminals each comprises the extending piece and the leg portion, and
an extending direction of the leg portion of the first reinforcing terminal and an extending direction of the leg portion of the second reinforcing terminal are set to different directions from each other.

13. The connector of claim 12, wherein
the leg portion of the first reinforcing terminal extends in a direction of separating from the shell toward a side of the shell, and
the leg portion of the second reinforcing terminal extends in the direction of opening of the opening portion.

14. The connector of claim 12, wherein
the leg portion of the first reinforcing terminal extends in a direction of separating from the shell toward a side of the shell, and
the leg portion of the second reinforcing terminal extends such that, as the leg portion of the second, reinforcing terminal extends toward the opening portion of the shell, the leg portion of the second reinforcing terminal gradually separates from the shell toward the side of the sell.
